(19) United States
(12) Patent Application Publication
(10) Pub. No.: US 2002/0142568 A1
(43) Pub. Date: Oct. 3, 2002

(54) Method and system for efficiently scheduling multi-chamber fabrication tool capacity

(75) Inventors: Chii-Hwang Chang, Tau-Yung (TW); Shih-Fang Chen, Sanchung (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.,

(21) Appl. No.: 09/818,313

(22) Filed: Mar. 27, 2001

(51) Int. Cl. C23F 1/00; H01L 21/04

(52) U.S. Cl. 438/510

(57) ABSTRACT

Within both a method for operating a multi-chamber fabrication tool and a system for operating the multi-chamber fabrication tool, there is first provided a multi-chamber fabrication tool comprising a series of chambers. There is also defined for each chamber within the series of chambers a minimum of one fabrication process to provide a series of fabrication processes corresponding with the series of chambers, wherein at least one fabrication process may be undertaken within more than one chamber and at least one chamber has defined therein more than one fabrication process including the at least one fabrication process which may be undertaken within more than one chamber. There is also processed within the multi-chamber fabrication tool a substrate while employing the at least one fabrication process which may be undertaken within more than one chamber, wherein a chamber within which is processed the substrate while employing the at least one fabrication process which may be undertaken within more than one chamber is selected such as to optimize utilization of the multi-chamber fabrication tool.

### BACKGROUND OF THE INVENTION

b 1. Field of the Invention

The present invention relates generally to methods and systems for scheduling multi-chamber fabrication tool capacity. More particularly, the present invention relates to methods and systems for efficiently scheduling multi-chamber fabrication tool capacity.

2. Description of the Related Art

Microelectronic fabrications are formed from microelectronic substrates over which are formed patterned microelectronic conductor layers which are separated by microelectronic dielectric layers.

As microelectronic fabrication integration levels have increased and patterned microelectronic conductor layer dimensions have decreased, it has become common in the art of microelectronic fabrication to employ when fabricating microelectronic fabrications multi-chamber fabrication tools, which are generally also referred to cluster tools, for purposes of fabricating microelectronic layers and microelectronic structures when fabricating microelectronic fabrications.

Multi-chamber fabrication tools are desirable within the art of microelectronic fabrication for purposes of fabricating microelectronic layers and microelectronic structures when fabricating microelectronic fabrications insofar as multi-chamber fabrication tools, in particular as employed within the context of vacuum process methods for fabricating microelectronic layers and microelectronic structures when fabricating microelectronic fabrications, allow for fabricating microelectronic fabrications while employing multiple separate vacuum process steps within multiple separate but interconnected vacuum process chambers within a multi-chamber fabrication tool without need for multiple vacuum process chamber pump down process cycles and vacuum process chamber backfill process cycles which would otherwise be employed for fabricating microelectronic layers and microelectronic structures when fabricating microelectronic fabrications while employing multiple separate vacuum process steps which might otherwise be undertaken while employing multiple separate and not interconnected vacuum process chambers within a series of fabrication tools which does not comprise a multi-chamber fabrication tool.

While multi-chamber fabrication tools are thus clearly desirable in the art of microelectronic fabrication for fabricating, with enhanced fabrication efficiency, microelectronic layers and microelectronic structures when fabricating microelectronic fabrications, multi-chamber fabrication tools are nonetheless not entirely without problems in the art of microelectronic fabrication for fabricating, with enhanced fabrication efficiency, microelectronic layers and microelectronic structures when fabricating microelectronic fabrications.

In that regard, while multi-chamber fabrication tools do in fact provide for enhanced microelectronic fabrication efficiency incident to avoidance of multiple vacuum process chamber pump down process cycles and vacuum process chamber backfill process cycles when fabricating microelectronic fabrications, efficient scheduling and utilization of multi-chamber fabrication tool capacity is nonetheless not always readily achievable in the art of microelectronic fabrication insofar as there often exist competing priorities and competing needs for individual process chamber capacity within overall multi-chamber fabrication tool capacity.

It is thus desirable in the art of microelectronic fabrication to provide methods and systems for more efficiently utilizing multi-chamber fabrication tool capacity when fabricating microelectronic layers and microelectronic structures when fabricating microelectronic fabrications.

It is towards the foregoing object that the present invention is directed.

Various methods, apparatus and systems have been disclosed in the art of microelectronic fabrication for more efficiently utilizing multi-chamber fabrication tool capacity when fabricating while employing a multi-chamber fabrication tool a series of microelectronic fabrications within the multi-chamber fabrication tool.

For example, Venkatesh et al., in U.S. Pat. No. 6,074,443, disclose a method and an apparatus for efficiently utilizing within a multi-chamber semiconductor substrate fabrication tool which employs a multiple blade semiconductor substrate transfer robot a multi-chamber semiconductor substrate fabrication tool capacity. To realize the foregoing result, the method and the apparatus provide that when transferring within the multi-chamber semiconductor substrate fabrication tool the series of semiconductor substrates while employing the multiple blade robot there is dynamically assigned a series of priorities to a series of process chambers within the multi-chamber semiconductor substrate fabrication tool and wherein, given adequate intervening time, a semiconductor substrate transfer within the multi-chamber semiconductor substrate fabrication tool is undertaken with respect to a lower priority process chamber within the multi-chamber semiconductor substrate fabrication tool prior to a higher priority process chamber within the multi-chamber semiconductor substrate fabrication tool.

Desirable in the art of microelectronic fabrication are additional methods and systems which may be employed for more efficiently utilizing multi-chamber fabrication tool capacity when fabricating microelectronic fabrications.

It is towards the foregoing object that the present invention is directed.

### SUMMARY OF THE INVENTION

A first object of the present invention is to provide a method for operating a multi-chamber fabrication tool and a system for operating the multi-chamber fabrication tool.

A second object of the present invention is to provide the method for operating the multi-chamber fabrication tool and the system for operating the multi-chamber fabrication tool in accord with the first object of the present invention, wherein the method for operating the multi-chamber fabrication tool and the system for operating the multi-chamber fabrication tool provide for enhanced utilization of multi-chamber fabrication tool capacity when fabricating a substrate within the multi-chamber fabrication tool.

A third object of the present invention is to provide the method for operating the multi-chamber fabrication tool and the system for operating the multi-chamber fabrication tool in accord with the first object of the present invention and the second object of the present invention, wherein the method for operating the fabrication tool and the system for operating the fabrication tool are readily commercially implemented.

In accord with the objects of the present invention, there is provided by the present invention a method for operating a multi-chamber fabrication tool and a system for operating the multi-chamber fabrication tool.

To practice the method of the present invention, there is first provided a multi-chamber fabrication tool comprising a series of chambers. There is then defined for each chamber within the series of chambers a minimum of one fabrication process to provide a series of fabrication processes corresponding with the series of chambers, wherein at least one fabrication process may be undertaken within more than one chamber and at least one chamber has defined therein more than one fabrication process including the at least one fabrication process which may be undertaken within more than one chamber. There is then processed within the multi-chamber fabrication tool a substrate while employing the at least one fabrication process which may be undertaken within more than one chamber, wherein a chamber within which is processed the substrate while employing the at least one fabrication process which may be undertaken within more than one chamber is selected such as to optimize utilization of the multi-chamber fabrication tool.

The present invention provides a method for operating a multi-chamber fabrication tool and a system for operating the multi-chamber fabrication tool, wherein the method for operating the multi-chamber fabrication tool and the system for operating the multi-chamber fabrication tool provide for enhanced utilization of multi-chamber fabrication tool capacity when fabricating a substrate within the multi-chamber fabrication tool.

The method of the present invention and the system of the present invention realize the foregoing object by defining for each chamber within a multi-chamber fabrication tool comprising a series of chambers a minimum of one fabrication process to provide a series of fabrication processes corresponding with the series of chambers, wherein at least one fabrication process may be undertaken within more than one chamber and at least one chamber has defined therein more than one fabrication process including the at least one fabrication process which may be undertaken within more than one chamber. There may then be processed within the multi-chamber fabrication tool a substrate while employing the at least one fabrication process which may be undertaken within more than one chamber, wherein a chamber within which is processed the substrate while employing the at least one fabrication process which may be undertaken within more than one chamber is selected such as to optimize utilization of the multi-chamber fabrication tool.

The method of the present invention and the system of the present invention are readily commercially implemented.

As will be illustrated in greater detail within the context of the Description of the Preferred Embodiment as set forth below, the method of the present invention and the system of the present invention may be implemented employing apparatus as are generally available in the art of microelectronic fabrication, but employed within the context specific operational limitations which provide at least in part the present invention. Since it is at least in part a series of operational limitations which provides at least in part the present invention, rather than the existence of apparatus which provides the present invention, the method of the present invention and the system of the present invention are readily commercially implemented.

### BRIEF DESCRIPTION OF THE DRAWINGS

The objects, features and advantages of the present invention are understood within the context of the Description of the preferred Embodiment, as set forth below. The Description of the preferred Embodiment is understood within the context of the accompanying drawings, which form a material part of this disclosure, wherein:

FIG. 1 shows a schematic plan view diagram of a multi-chamber fabrication tool with respect to which the present invention may be practiced.

FIG. 2 shows a schematic process flow diagram illustrating a series of process steps in accord with the method of resent invention.

FIG. 3 shows a schematic block diagram illustrating various components in accord with the system of the present invention.

### DESCRIPTION OF THE PREFERRED EMBODIMENT

The present invention provides a method for operating a multi-chamber fabrication tool and a system for operating the multi-chamber fabrication tool, wherein the method for operating the multi-chamber fabrication tool and the system for operating the multi-chamber fabrication tool provide for enhanced utilization of multi-chamber fabrication tool capacity when fabricating a substrate within the multi-chamber fabrication tool.

The method of the present invention and the system of the present invention realize the foregoing object by defining for each chamber within a multi-chamber fabrication tool comprising a series of chambers a minimum of one fabrication process to provide a series of fabrication processes corresponding with the series of chambers, wherein at least one fabrication process may be undertaken within more than one chamber and at least one chamber has defined therein more than one fabrication process including the at least one fabrication process which may be undertaken within more than one chamber. There may then be processed within the multi-chamber fabrication tool a substrate while employing the at least one fabrication process which may be undertaken within more than one chamber, wherein a chamber within which is processed the substrate while employing the at least one fabrication process which may be undertaken within more than one chamber is selected such as to optimize utilization of the multi-chamber fabrication tool.

Although the preferred embodiment of the present invention provides particular value within the context of fabricating a semiconductor integrated circuit microelectronic fabrication within a vacuum process multi-chamber fabrication tool, the present invention may be employed for fabricating microelectronic fabrications including but not limited to integrated circuit microelectronic fabrications, ceramic substrate microelectronic fabrications, solar cell optoelectronic microelectronic fabrications, sensor image array optoelectronic microelectronic fabrications and display image array optoelectronic microelectronic fabrications within multi-chamber fabrication tools which need not necessarily be limited to vacuum process multi-chamber fabrication tools.

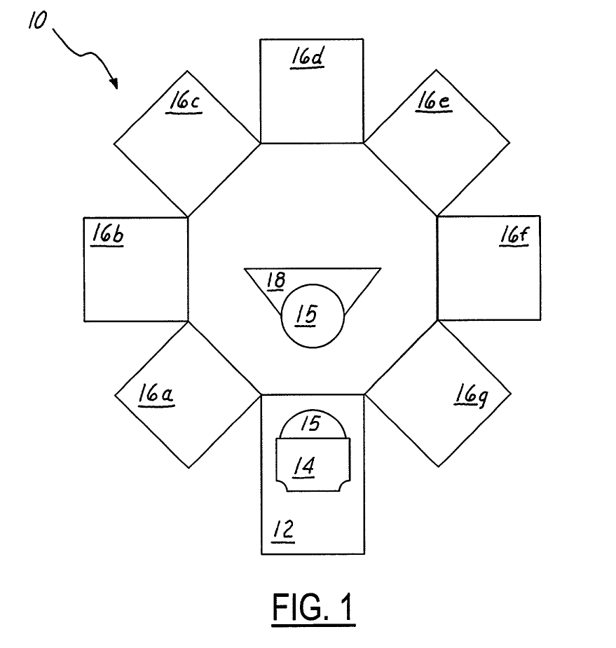

Referring now to FIG. 1 there is shown a schematic plan view diagram of a multi-chamber fabrication tool with respect to which may be practiced the present invention.

Shown in general within the schematic plan view diagram of FIG. 1 is a multi-chamber fabrication tool 10 which comprises in a first instance a load-lock 12 within which is positioned a cassette 14 having contained therein a plurality of substrates 15. Also shown within the schematic plan view diagram of FIG. 1 is a series of chambers 16a, 16b, 16c, 16d, 16e, 16f and 16g which surround a core of the multi-chamber fabrication tool 10, and wherein within the core of the multi-chamber fabrication tool 10 there is positioned a transfer robot 18 which is intended to transfer a substrate 15 to and from the cassette 14 and various of the chambers 16a, 16b, 16c, 16d, 16e, 16f and 16g.

As is understood by a person skilled in the art, and within the context of the present invention, it is towards the object of providing an efficient utilization of multi-chamber fabrication tool 10 capacity that the present invention is directed.

As is further understood by a person skilled in the art, while the preferred embodiment of the present invention illustrates the present invention within the context of a multi-chamber fabrication tool 10 comprising a single load-lock 12 and seven chambers 16a, 16b, 16c, 16d, 16e, 16f and 16g arranged in an octagonal configuration surrounding the transfer robot 18 which is intended to transfer the plurality of substrates 15 between the cassette 14 positioned within the load lock 12 and the series of seven chambers 16a, 16b, 16c, 16d, 16e, 16f and 16g, the present invention is also applicable to multi-chamber fabrication tools having alternative numbers of load locks and chambers, as well as with alternative geometric dispositions of load locks and chambers with respect to a transfer robot intended to transfer a substrate from a cassette positioned within a load lock to a chamber within a series of chambers. Such alternative multi-chamber fabrication tool configurations are illustrated, for example and without limitation, within Venkatesh et at., as cited within the Description of the Related Art, the disclosure of which is incorporated herein fully by reference. Typically and preferably, within the context of the present invention the number of chambers within a multi-chamber fabrication tool with respect to which is practiced the present invention is at least about 4 and typically and preferably equal to the total number of process chambers.

As noted above, within the preferred embodiment of the present invention, and although the present invention is not strictly and specifically limited thereto, typically and preferably at least several of the chambers 16a, 16b, 16c, 16d, 16e, 16f and 16g will be employed for vacuum fabrication processes, such as but not limited to vacuum implantation fabrication processes, vacuum etch fabrication processes and vacuum deposition fabrication processes.

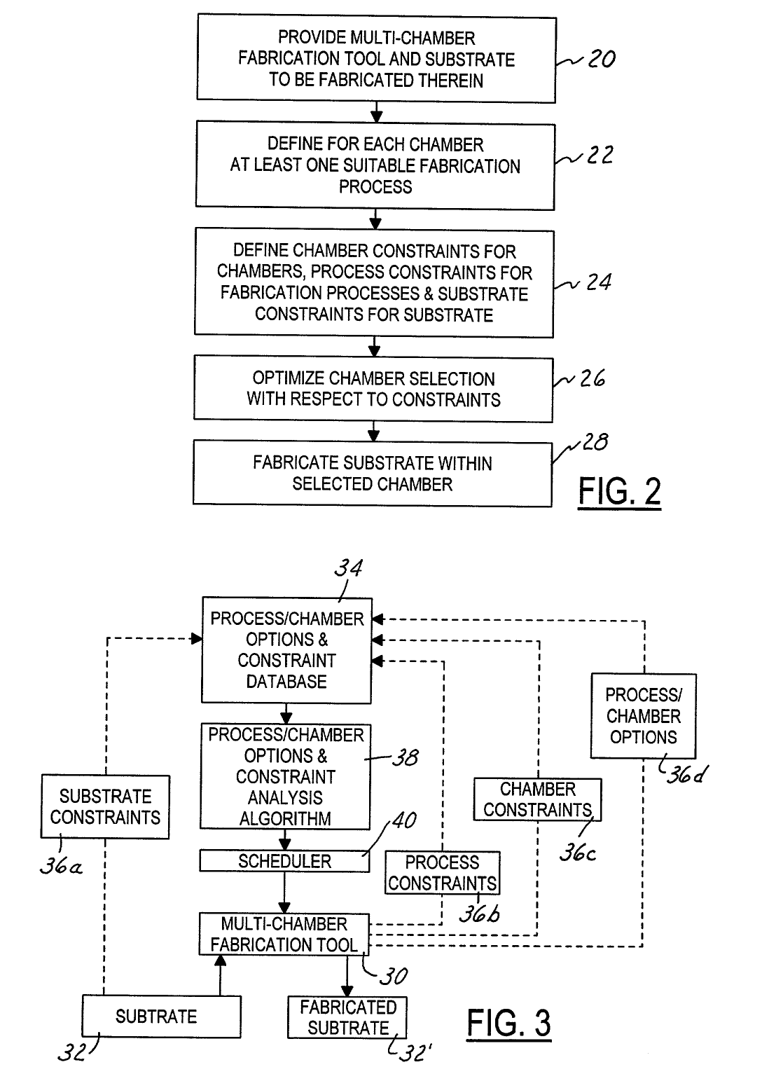

Referring now to FIG. 2, there is shown a schematic process flow diagram illustrating a series of process steps in accord with the method of the present invention.

Shown in FIG. 2, and in accord with the block which corresponds with reference numeral 20, there is first provided a multi-chamber fabrication tool and a substrate to be fabricated within the multi-chamber fabrication tool.

Within the preferred embodiment of the present invention with respect to the multi-chamber fabrication tool, the multi-chamber fabrication tool is typically and preferably a multi-chamber fabrication tool analogous or equivalent to the multi-chamber fabrication tool 10 as illustrated within the context of FIG. 1, and as discussed in greater detail above, also within the context of FIG. 1.

Within the preferred embodiment of the present invention with respect to the substrate to be fabricated within the multi-chamber fabrication tool, and also while the present invention provides particular value within the context of fabricating a semiconductor substrate within a multi-chamber fabrication tool, the substrate to be fabricated within the multi-chamber fabrication tool may be selected from the group of substrates employed when fabricating microelectronic fabrications selected from the group including but not limited to integrated circuit microelectronic fabrications, ceramic substrate microelectronic fabrications, solar cell optoelectronic microelectronic fabrications, sensor image array optoelectronic microelectronic fabrications and display image array optoelectronic microelectronic fabrications.

Referring again to FIG. 2, and in accord with the block which corresponds with reference numeral 22, there is then defined for each chamber within the multi-chamber fabrication tool at least one suitable fabrication process, to provide a series of fabrication processes corresponding with the series of chambers within the multi-chamber fabrication tool.

Within the method of the present invention and the preferred embodiment of the method of the present invention, at least one fabrication process within the series of fabrication processes may be undertaken within more than one chamber within the series of chambers within the multi-chamber fabrication tool and at least one chamber within the multi-chamber fabrication tool has defined therein more than one fabrication process including the at least one fabrication process within the series of fabrication processes which may be undertaken within the more than one chamber within the series of chambers within the multi-chamber fabrication tool.

Referring again to FIG. 2, and in accord with the block which corresponds with reference numeral 24, there is defined for: (1) each chamber within the series of chambers a series of chamber constraints; (2) each process within the series of processes a series of process constraints; and (3) the substrate a series of substrate constraints.

Within the preferred embodiment of the present invention with respect to the series of chamber constraints, the series of chamber constraints will typically and preferably, but not exclusively, be directed towards chamber constraints such as but not limited to preventive maintenance chamber constraints, chamber monitor chamber constraints, chamber idle time chamber constraints and chamber reconfiguration chamber constraints.

In addition, within the preferred embodiment of the present invention with respect to the series of process constraints, the series of process constraints will typically and preferably, but not exclusively, be directed towards process constraints such as but not limited to process reconfiguration process constraints and process monitor process constraints.

Finally, within the preferred embodiment of the present invention with respect to the series of substrate constraints, the series or substrate constraints will typically and preferably, but not exclusively, be directed towards substrate constraints such as but not limited to substrate aging substrate constraints.

Referring again to FIG. 2 and in accord with the block which corresponds with reference numeral 26, there is then optimized a chamber selection within the multi-chamber fabrication tool, for fabricating the substrate within the multi-chamber fabrication tool, wherein the chamber selection is optimized within the context of the series of process constraints, the series of chamber constraints and the series of substrate constraints, such as to in general optimize utilization of the multi-chamber fabrication tool.

As is understood by a person skilled in the art, in order to provide for optimized chamber selection within the multi-chamber fabrication tool for fabricating the substrate within the multi-chamber fabrication tool within the context of the series of chamber constraints, the series of process constraints and the series of substrate constraints, it is typical and preferred that the series of chamber constraints, the series of process constraints and the series of substrate constraints, as well as the series of process and chamber options be entered into a database and that there be developed an algorithm which operates in conjunction with the series of chamber constraints, the series of process constraints and the series of substrate constraints such as to prioritize the constraints and thus select a chamber within the available process and chamber options within the multi-chamber fabrication tool in accord with the prioritized constraints or in the alternative to select a chamber within the multi-chamber fabrication tool without violating any of the constraints, either of which may be viewed as optimizing utilization of the multi-chamber fabrication tool.

Integral to the application of the algorithm with respect to the series of chamber constraints, the series of process constraints and the series of substrate constraints, there will typically and preferably also be determined a sub-series of chambers which are prohibited with respect to a specific process, a sub-series of chambers which are acceptable with respect to a specific process and a sub-series of chambers which need reconfiguration with respect to a specific process.

Referring again to FIG. 2, and in accord with the block which corresponds with reference numeral 28, there is then fabricated the substrate within the selected chamber (with reconfiguration if needed), as selected in accord with the block which corresponds with reference numeral 26, and as is discussed in further detail above.

Referring now to FIG. 3, there is shown a schematic block diagram illustrating various components in accord with a system in accord with the present invention which may be employed to practice the method in accord with the present invention.

Shown in FIG. 3, in a first instance, is a multi-chamber fabrication tool 30 within a chamber within which it is desired to fabricate a substrate 32 to provide a fabricated substrate 32′.

Within the preferred embodiment of the present invention, the multi-chamber fabrication tool 30 as illustrated within the schematic diagram of FIG. 3 corresponds with the multi-chamber fabrication tool 10 as illustrated within the schematic diagram of FIG. 1. Similarly, within the preferred embodiment of the present invention with respect to the substrate 32 which is desired to be fabricated within the chamber within the multi-chamber fabrication tool 30 to provide the fabricated substrate 32′, the substrate 32 as illustrated within the schematic diagram of FIG. 3 is otherwise analogous or equivalent to the substrate 15 as illustrated within the schematic diagram of FIG. 1.

As is further illustrated within the schematic diagram of FIG. 3, and in accord with the blocks which correspond with reference numerals 36a, 36b, 36c and 36d, there is determined a series of substrate constraints, a series of process constraints, a series of chamber constraints and a series of process/chamber options, all of which are entered into and catalogued within a process/chamber options and constraint database 34 upon which operates a constraint analysis algorithm 38 which in turn drives a scheduler 40 for purposes of selecting within the multi-chamber fabrication tool 30 a selected chamber for fabricating the substrate 32 to provide the fabricated substrate 32′. As is understood by a person skilled in the art, the process/chamber options and constraint database 34, the constraint analysis algorithm 38 and the scheduler 40 are typically and preferably components of, or integrated within, a computer system.

Absent in particular within the schematic diagram of FIG. 3 is any user interface as directed towards the computer system, although entry of various of the process/chamber options and various of the constraints into the process/chamber options and constraint database 34 is presumably undertaken either directly or indirectly through a user interface, such as but not limited to a graphical user interface.

Upon fabricating a 15 substrate as illustrated within the schematic plan view diagram of FIG. 1 or a substrate 32 as illustrated within the schematic block diagram of FIG. 3 within a chamber within a multi-chamber fabrication tool 10 as illustrated within the schematic plan view diagram of FIG. 1 or a multi-chamber fabrication tool 30 as illustrated within the schematic block diagram of FIG. 3, within the context of method as illustrated within the schematic process flow diagram of FIG. 2, there is fabricated the substrate to provide the fabricated substrate while operating the multi-chamber fabrication tool with enhanced efficiency.

The present invention realizes the foregoing object by considering when selecting a chamber within the multi-chamber fabrication tool within which is fabricated the substrate to provide the fabricated substrate a series of constraints including substrate constraints, process constraints and chamber constraints, within the context of a constraint analysis algorithm which optimizes the selection of the chamber, from a plurality of suitable chambers, within the multi-chamber fabrication tool.

As is understood by a person skilled in the art, the preferred embodiment of the present invention is illustrative of the present invention rather than limiting of the present invention. Revisions and modifications may be made to materials, substrates and apparatus which are employed within the context of the preferred embodiment of the present invention while still providing a method in accord with the present invention and a system in accord with the present invention, further in accord with the accompanying claims.

What is claimed is:

1. A method for operating a multi-chamber fabrication tool comprising:
providing a multi-chamber fabrication tool comprising a series of chambers;
defining for each chamber within the series of chambers a minimum of one fabrication process to provide a series of fabrication processes corresponding with the series of chambers, wherein at least one fabrication process may be undertaken within more than one chamber and at least one chamber has defined therein more than one fabrication process including the at least one fabrication process which may be undertaken within more than one chamber;
processing within the multi-chamber fabrication tool a substrate while employing the at least one fabrication process which may be undertaken within more than one chamber, wherein a chamber within which is processed the substrate while employing the at least one fabrication process which may be undertaken within more than one chamber is selected such as to optimize utilization of the multi-chamber fabrication tool.

2. The method of claim 1 wherein the substrate is employed within a microelectronic fabrication selected from the group consisting of integrated circuit microelectronic fabrications, ceramic substrate microelectronic fabrications, solar cell optoelectronic microelectronic fabrications, sensor image array optoelectronic microelectronic fabrications and display image array optoelectronic microelectronic fabrications.

3. The method of claim 1 wherein the series of chambers comprises at least about 1 chamber.

4. The method of claim 1 wherein the series of fabrication processes is selected from the group consisting of vacuum etch processes, vacuum deposition processes and vacuum implantation processes

5. The method of claim 1 further comprising:
defining a series of chamber constraints for the series of chambers;
defining a series of process constraints for the series of processes; and
defining a series of substrate constraints for the substrate.

6. The method of claim 5 wherein the series of chamber constraints, the series of process constraints and the series of substrate constraints is prioritized through use of an algorithm when selecting the chamber within which is processed the substrate.

7. A system for operating a multi-chamber fabrication tool comprising:
a multi-chamber fabrication tool comprising a series of chambers;
means for cataloging for each chamber within the series of chambers a minimum of one fabrication process to provide a series of fabrication processes corresponding with the series of chambers, wherein at least one fabrication process may be undertaken within more than one chamber and at least one chamber has catalogued therein more than one fabrication process including the at least one fabrication process which may be undertaken within more than one chamber;
means for selecting within the multi-chamber fabrication tool a chamber within which is processed a substrate while employing the at least one fabrication process which may be undertaken within more than one chamber, the means for selecting providing a selected chamber selected such as to optimize utilization of the multi-chamber fabrication tool.

8. The system of claim 7 wherein the substrate is employed within a microelectronic fabrication selected from the group consisting of integrated circuit microelectronic fabrications, ceramic substrate microelectronic fabrications, solar cell optoelectronic microelectronic fabrications, sensor image array optoelectronic microelectronic fabrications and display image array optoelectronic microelectronic fabrications.

9. The system of claim 7 wherein the series of chambers comprises at least about 1 chamber.

10. The system of claim 7 wherein the series of fabrication processes is selected from the group consisting of vacuum etch processes, vacuum deposition processes and vacuum implantation processes

11. The system of claim 7 further comprising means for cataloging a series of chamber constraints for the series of chambers, a series of process constraints for the series of processes and a series of substrate constraints for the substrate.

12. The system of claim 11 wherein the series of chamber constraints, the series of process constraints and the series of substrate constraints is prioritized through use of an algorithm when selecting the selected chamber within which is processed the substrate.
